(19) United States
(12) Patent Application Publication
(10) Pub. No.: US 2017/0030989 A1
(43) Pub. Date: Feb. 2, 2017

(54) Body-CoilL-Constrained Reconstruction of Undersampled Magnetic Resonance Imaging Data

(71) Applicant: THE GENERAL HOSPITAL CORPORATION, Boston, MA (US)

(72) Inventor: MATTHEW DYLAN TISDALL, Charlestown, MA (US)

(21) Appl. No.: 15/303,926

(22) PCT Filed: Apr. 23, 2015
(86) PCT No.: PCT/US15/27336

§ 371 Date: Oct. 13, 2016

Related U.S. Application Data
(60) Provisional application No. 61/983,255, filed on Apr. 23, 2014.

(51) Int. Cl. G01R 33/561; G01R 33/56; G01R 33/565

(52) U.S. Cl. CPC G01R 33/5611; G01R 33/56509; G01R 33/5608

(57) ABSTRACT

Systems and methods for reconstructing images from data acquired with a magnetic resonance imaging (“MRI”) system are provided. Data are acquired using both a body coil and a multichannel matrix coil. The body coil measurements can be used to constrain the solution space for the image reconstruction from the data acquired using the multichannel matrix coil. The resulting images have the flat sensitivity profile of the body coil, but signal-to-noise ration and undersampling-acceleration gained from a matrix coil.

### CROSS-REFERENCE TO RELATED APPLICATIONS

This application claims the benefit of U.S. Provisional Patent Application Ser. No. 61/983,255, filed on Apr. 23, 2014, and entitled “BODY-COIL-CONSTRAINED RECONSTRUCTION OF UNDERSAMPLED MAGNETIC RESONANCE IMAGING DATA.”

### STATEMENT REGARDING FEDERALLY SPONSORED RESEARCH

This invention was made with government support under HD074649 awarded by the National Institutes of Health. The government has certain rights in the invention.

### BACKGROUND OF THE INVENTION

The field of the invention is systems and methods for magnetic resonance imaging (“MRI”). More particularly, the invention relates to systems and methods for reconstructing images from data acquired using an MRI system and both a body coil and a matrix coil.

Parallel MRI algorithms focus on using a multichannel coil array to reconstruct an image from undersampled MRI data, which allows for a significant shortening in scan time. In practice, these algorithms have different deficiencies. For instance, GRAPPA provides less acceleration than might be theoretically predicted (e.g., max 2×2 acceleration with a 32-channel coil). As another example, SENSE magnifies errors in the coil sensitivity maps, and previous iterative non-linear solvers for the full signal equation have tended to produce images with significant bias fields.

### SUMMARY OF THE INVENTION

The present invention overcomes the aforementioned drawbacks by providing a method for producing an image of a subject using a magnetic resonance imaging (“MRI”) system. A first dataset is acquired from the subject using a body radio frequency (“RF”) coil of the MRI system, and a second dataset is acquired from the subject using a matrix RF coil. Both of these datasets can be significantly undersampled relative to the desired number of samples in k-space. From the acquired first and second datasets, the following are jointly estimated: a “true” signal, weighted by a sensitivity of the body RF coil, and a kernel for each channel in the matrix coil. An image volume can then be constructed from the estimated true signal.

The foregoing and other aspects and advantages of the invention will appear from the following description. In the description, reference is made to the accompanying drawings that form a part hereof, and in which there is shown by way of illustration a preferred embodiment of the invention. Such embodiment does not necessarily represent the full scope of the invention, however, and reference is made therefore to the claims and herein for interpreting the scope of the invention.

### BRIEF DESCRIPTION OF THE DRAWINGS

FIG. 1 is a flowchart setting forth the steps of an example method for reconstructing an image of a subject using a body-coil-constrained reconstruction of data acquired with an MRI system;

FIG. 2 is a block diagram of an example of a magnetic resonance imaging (“MRI”) system.

### DETAILED DESCRIPTION OF THE INVENTION

Described here are systems and methods for reconstructing images from data acquired with a magnetic resonance imaging (“MRI”) system. The image reconstruction method described here, when paired with an appropriate data acquisition strategy, reconstructs high-quality magnitude and phase images, even from data acquired with significant undersampling.

For instance, data can be acquired with an MRI system using a sampling strategy, in which one or more reference measurements are obtained with the body coil of the MRI system. These body coil measurements can be used to constrain the solution space for the image reconstruction, as will be described below in detail.

The image reconstruction can be highly parallelized to reconstruct bias-field-free images from significantly undersampled data (e.g., data acquired with an acceleration factor R≧7 with a 32-channel coil).

Although the image reconstruction method can be viewed as an image-domain algorithm, such as SENSE, it can also be viewed as a joint-fitting method that estimates GRAPPA-type kernels. Instead of unmixing each channel as is normally done in GRAPPA, however, the reconstruction only unmixes the body coil from all the other channels, while simultaneously estimating the signal as it would be observed in a synthetic high-SNR body coil.

The systems and methods described here overcome limitations and drawbacks to previous reconstruction methods, such as those implementing the Gauss-Newton method to jointly estimate the coil sensitivities and “true” signal using a smoothness constraint on the coil sensitivities. An example of the Gauss-Newton method is described by M. Uecker, et al., in “Image reconstruction by regularized nonlinear inversion-joint estimation of coil sensitivities and image content,” Magn Reson Med., 2008; 60(3):674-682. With such previous methods, the smoothness constraint can be expressed implicitly by representing the coil sensitivities with compact representations in the Fourier domain, as described by M. Tissdall, et al., in “Joint Estimation of Signal and Coil Sensitivities with a Bilinear Model,” ISMRM Workshop on Parallel MRI, 2009. This formulation allows for significant reduction in the number of variables being optimized. The previous methods, however, suffer from an inability to distinguish variations in coil sensitivities from slowly varying changes in “true” signal intensity. The systems and methods described here overcome this drawback by utilizing a reconstruction that is constrained by information derived from the body coil of the MRI system.

Two parameters can be jointly estimated from data acquired with the body coil and data acquired with a matrix coil. The first is the “true” k-space signal weighted by the body coil sensitivity. The second is the compact Fourier representation of each matrix channel's sensitivity convolved with the Fourier representation of the inverse of the body coil's sensitivity. For each channel, the second parameter can be viewed as the kernel that, convolved with the estimated body-coil-weighted signal, gives the estimate of the k-space for that channel. On the assumption that the body coil's sensitivity is extremely compact in the Fourier domain (e.g., just a DC term), then it is contemplated that the kernels estimated as the second parameter noted above will be almost as compact as the true channel sensitivities. Performing an inverse Fourier transform on the estimated body-coil k-space estimated as the first parameter gives an estimate of the “true” image, weighted with the body coil's sensitivity.

In some embodiments, the estimation problem is framed as a minimization of the weighted mean squared difference (i.e., error) between the complex measured k-space data and the complex k-space data predicted by the two estimated parameters discussed above. As one example, the weights in the weighted mean squared difference can be set to 0 for k-space samples that were not acquired, and 1 for k-space samples that were acquired. In some instances, it can be advantageous to use separate weights for each channel as this will allow samples that were acquired with the body coil to be readily distinguished from samples acquired with the matrix coil. As another example, binary weights do not need to be used. Thus, the reconstruction can be expanded, at no additional computational cost, to account for additional weighting metrics (e.g., from motion-tracking) at each point in k-space.

As a specific, non-limiting example, minimization can be performed using a Levenberg-Marquardt (“LM”) algorithm, with a diagonally-preconditioned conjugate gradient algorithm iteratively solving each LM-step. The parameterization of the model can be selected to allow the performance of these operations on Cartesian-sampled data without forming any of the matrices normally implied by the LM algorithm. Instead, the “matrix-times-vector” operation can be decomposed into convolutions, element-wise vector multiplications, and inner-products with shifted versions of the vector. These operations are highly parallelizable, and thus can be run on a graphics processing unit (“GPU”).

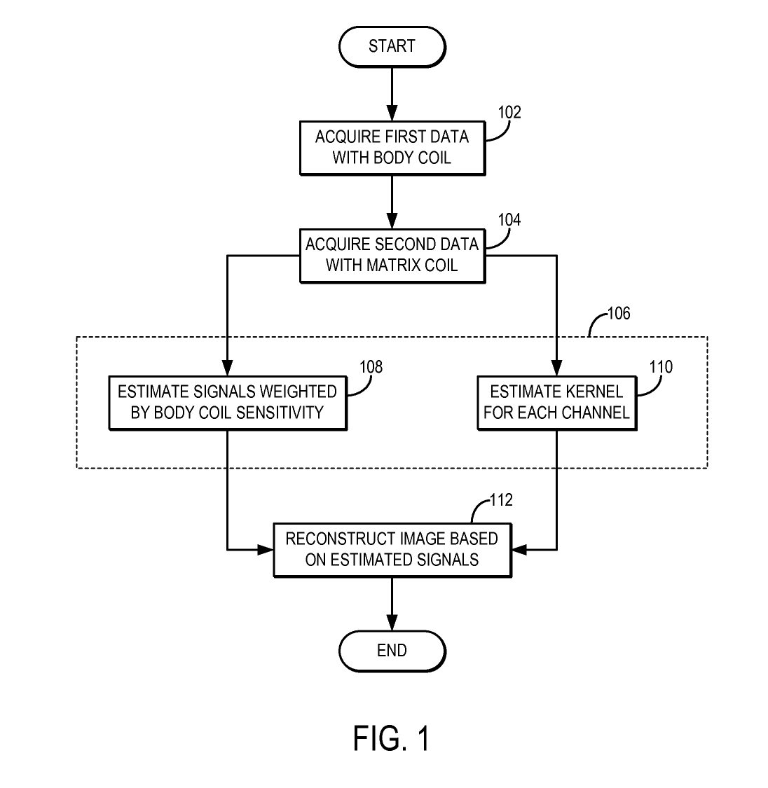

Referring now to FIG. 1, an example of a method for reconstructing an image of a subject using a body-coil-constrained reconstruction of data acquired with an MRI system is illustrated. First data are acquired using the body coil of the MRI system, as indicated at step 102. Next, second data are acquired using a matrix coil, as indicated at step 104. In some embodiments, the first and second data can be acquired in a combined fashion. For instance, data can be acquired with both the body coil and the multichannel matrix coil in a combined fashion in a single scan. As one example, acquisitions with the body coil and the multichannel matrix coil can be performed sequentially. An another example, the acquisitions can be interleaved, and can be uniformly or non-uniformly interleaved.

Based on the first and second data, a joint-estimation is performed, as indicated generally at 106. This joint-estimation includes estimating a signal weighted by the body coil sensitivity, as indicated at step 108, and estimating a kernel for each channel in the matrix coil, as indicated at step 110. More particularly, the kernel that is estimated can be the compact Fourier representation of each matrix channel's sensitivity convolved with the Fourier representation of the inverse of the body coil's sensitivity. These estimated kernels are used as part of the joint-estimation process to estimate the body coil sensitivity-weighted signals, as described above. As an example, the joint estimation can be performed by iteratively minimizing a weighted least squared difference between the acquired data and the k-space data predicted based on the current estimate of the signal and kernels. As described above, in some embodiments, a Levenberg-Marquardt algorithm, with a diagonally-preconditioned conjugate gradient algorithm iteratively solving each LM-step, can be used to minimize the weighted least squared difference between the acquired and estimated data.

Based on this estimated data, a target image of the subject can be reconstructed, as indicated at step 112. For example, the target image can be reconstructed by taking the Fourier transform of the estimated body-coil weighted signal.

Systems and methods for reconstructing an image from undersampled multichannel data acquired with an MRI system, in which the acquired data includes some samples measured with the body coil, has been provided. The reconstruction produces high-quality images, even with large acceleration factors.

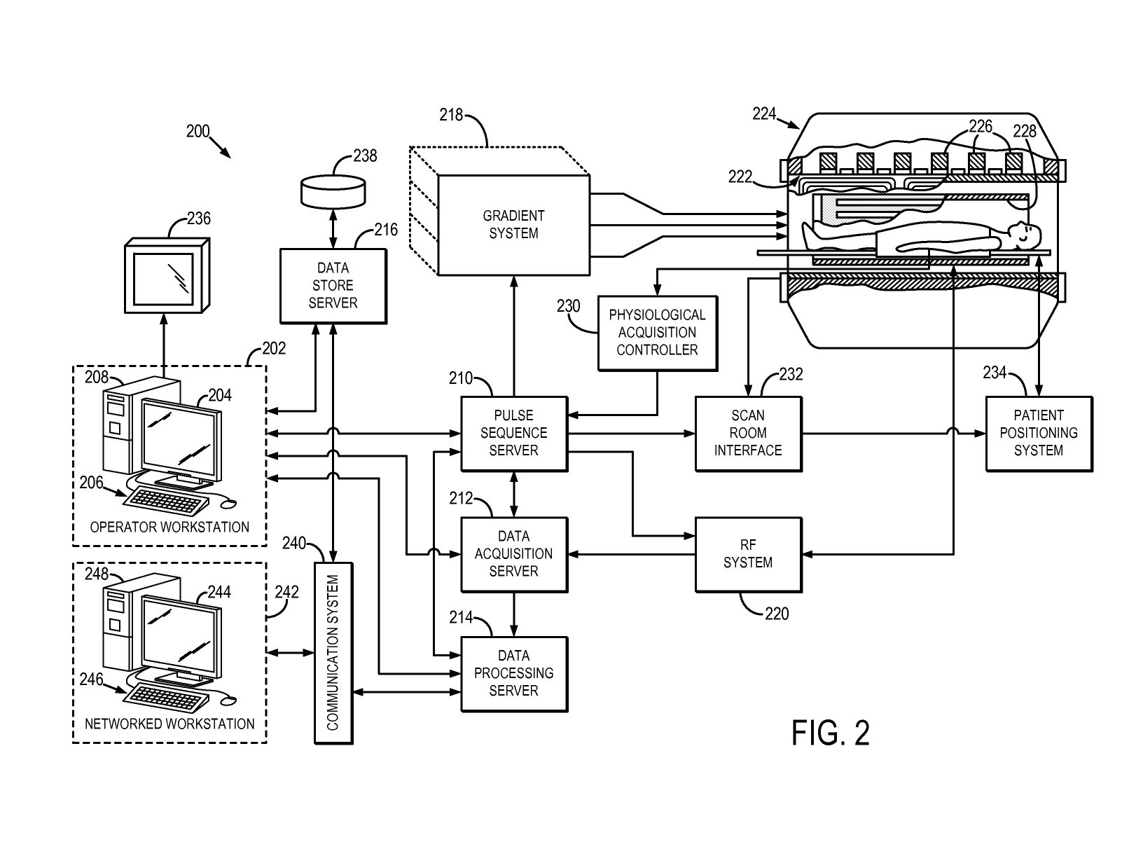

Referring particularly now to FIG. 2, an example of a magnetic resonance imaging (“MRI”) system 200 is illustrated. The MRI system 200 includes an operator workstation 202, which will typically include a display 204; one or more input devices 206, such as a keyboard and mouse; and a processor 208. The processor 208 may include a commercially available programmable machine running a commercially available operating system. The operator workstation 202 provides the operator interface that enables scan prescriptions to be entered into the MRI system 200. In general, the operator workstation 202 may be coupled to four servers: a pulse sequence server 210; a data acquisition server 212; a data processing server 214; and a data store server 216. The operator workstation 202 and each server 210, 212, 214, and 216 are connected to communicate with each other. For example, the servers 210, 212, 214, and 216 may be connected via a communication system 240, which may include any suitable network connection, whether wired, wireless, or a combination of both. As an example, the communication system 240 may include both proprietary or dedicated networks, as well as open networks, such as the internet.

The pulse sequence server 210 functions in response to instructions downloaded from the operator workstation 202 to operate a gradient system 218 and a radiofrequency (“RF”) system 220. Gradient waveforms necessary to perform the prescribed scan are produced and applied to the gradient system 218, which excites gradient coils in an assembly 222 to produce the magnetic field gradients Gₓ, G_{y}, and G_{z} used for position encoding magnetic resonance signals. The gradient coil assembly 222 forms part of a magnet assembly 224 that includes a polarizing magnet 226 and a whole-body RF coil 228.

RF waveforms are applied by the RF system 220 to the RF coil 228, or a separate local coil (not shown in FIG. 2), in order to perform the prescribed magnetic resonance pulse sequence. Responsive magnetic resonance signals detected by the RF coil 228, or a separate local coil (not shown in FIG. 2), are received by the RF system 220, where they are amplified, demodulated, filtered, and digitized under direction of commands produced by the pulse sequence server 210. The RF system 220 includes an RF transmitter for producing a wide variety of RF pulses used in MRI pulse sequences. The RF transmitter is responsive to the scan prescription and direction from the pulse sequence server 210 to produce RF pulses of the desired frequency, phase, and pulse amplitude waveform. The generated RF pulses may be applied to the whole-body RF coil 228 or to one or more local coils or coil arrays (not shown in FIG. 2).

The RF system 220 also includes one or more RF receiver channels. Each RF receiver channel includes an RF preamplifier that amplifies the magnetic resonance signal received by the coil 228 to which it is connected, and a detector that detects and digitizes the I and Q quadrature components of the received magnetic resonance signal. The magnitude of the received magnetic resonance signal may, therefore, be determined at any sampled point by the square root of the sum of the squares of the I and Q components:

M=\sqrt{I²+Q²}

and the phase of the received magnetic resonance signal may also be determined according to the following relationship:

$$ϕ = {tan}^{- 1} ( \frac{Q}{I} ) . \qquad ( 2 )$$

The pulse sequence server 210 also optionally receives patient data from a physiological acquisition controller 230. By way of example, the physiological acquisition controller 230 may receive signals from a number of different sensors connected to the patient, such as electrocardiograph (“ECG”) signals from electrodes, or respiratory signals from a respiratory bellows or other respiratory monitoring device. Such signals are typically used by the pulse sequence server 210 to synchronize, or “gate,” the performance of the scan with the subject's heart beat or respiration.

The pulse sequence server 210 also connects to a scan room interface circuit 232 that receives signals from various sensors associated with the condition of the patient and the magnet system. It is also through the scan room interface circuit 232 that a patient positioning system 234 receives commands to move the patient to desired positions during the scan.

The digitized magnetic resonance signal samples produced by the RF system 220 are received by the data acquisition server 212. The data acquisition server 212 operates in response to instructions downloaded from the operator workstation 202 to receive the real-time magnetic resonance data and provide buffer storage, such that no data is lost by data overrun. In some scans, the data acquisition server 212 does little more than pass the acquired magnetic resonance data to the data processor server 214. However, in scans that require information derived from acquired magnetic resonance data to control the further performance of the scan, the data acquisition server 212 is programmed to produce such information and convey it to the pulse sequence server 210. For example, during prescans, magnetic resonance data is acquired and used to calibrate the pulse sequence performed by the pulse sequence server 210. As another example, navigator signals may be acquired and used to adjust the operating parameters of the RF system 220 or the gradient system 218, or to control the view order in which k-space is sampled. In still another example, the data acquisition server 212 may also be employed to process magnetic resonance signals used to detect the arrival of a contrast agent in a magnetic resonance angiography (“MRA”) scan. By way of example, the data acquisition server 212 acquires magnetic resonance data and processes it in real-time to produce information that is used to control the scan.

The data processing server 214 receives magnetic resonance data from the data acquisition server 212 and processes it in accordance with instructions downloaded from the operator workstation 202. Such processing may, for example, include one or more of the following: reconstructing two-dimensional or three-dimensional images by performing a Fourier transformation of raw k-space data; performing other image reconstruction algorithms, such as iterative or backprojection reconstruction algorithms; applying filters to raw k-space data or to reconstructed images; generating functional magnetic resonance images; calculating motion or flow images; and so on.

Images reconstructed by the data processing server 214 are conveyed back to the operator workstation 202 where they are stored. Real-time images are stored in a data base memory cache (not shown in FIG. 2), from which they may be output to operator display 212 or a display 236 that is located near the magnet assembly 224 for use by attending physicians. Batch mode images or selected real time images are stored in a host database on disc storage 238. When such images have been reconstructed and transferred to storage, the data processing server 214 notifies the data store server 216 on the operator workstation 202. The operator workstation 202 may be used by an operator to archive the images, produce films, or send the images via a network to other facilities.

The MRI system 200 may also include one or more networked workstations 242. By way of example, a networked workstation 242 may include a display 244; one or more input devices 246, such as a keyboard and mouse; and a processor 248. The networked workstation 242 may be located within the same facility as the operator workstation 202, or in a different facility, such as a different healthcare institution or clinic.

The networked workstation 242, whether within the same facility or in a different facility as the operator workstation 202, may gain remote access to the data processing server 214 or data store server 216 via the communication system 240. Accordingly, multiple networked workstations 242 may have access to the data processing server 214 and the data store server 216. In this manner, magnetic resonance data, reconstructed images, or other data may exchanged between the data processing server 214 or the data store server 216 and the networked workstations 242, such that the data or images may be remotely processed by a networked workstation 242. This data may be exchanged in any suitable format, such as in accordance with the transmission control protocol (“TCP”), the internet protocol (“IP”), or other known or suitable protocols.

The present invention has been described in terms of one or more preferred embodiments, and it should be appreciated that many equivalents, alternatives, variations, and modifications, aside from those expressly stated, are possible and within the scope of the invention.

1. A method for producing an image of a subject using a magnetic resonance imaging (MRI) system, the steps of the method comprising:
(a) acquiring a first dataset from a subject using a body radio frequency (RF) coil of an MRI system;
(b) acquiring a second dataset from a subject using a matrix RF coil of the MRI system;
(c) jointly estimating from the acquired first and second datasets:
a signal weighted by a sensitivity of the body RF coil;
a kernel for each channel in the matrix coil; and and
(d) reconstructing an image of the subject based on the signal that is jointly-estimated in step (c).

2. The method as recited in claim 1, wherein the kernel estimated for a particular channel in step (c) comprises a compact Fourier representation of a matrix coil sensitivity for the particular channel convolved with a Fourier representation of an inverse of the sensitivity of the body coil.

3. The method as recited in claim 1, wherein step (c) includes iteratively minimizing a difference between the acquired first and second datasets and k-space data that is estimated by convolving each estimated kernel with the estimated signal weighted by a sensitivity of the body RF coil.

4. The method as recited in claim 3, wherein the difference that is minimized in step (c) is a least squares difference.

5. The method as recited in claim 4, wherein the least squares difference is a weighted least squares difference.

6. The method as recited in claim 5, wherein the weighted least squares difference uses a binary weighting.

7. The method as recited in claim 5, wherein the weighted least squared differences uses weightings that are based on a quality metric.

8. The method as recited in claim 7, wherein the quality metric is associated with subject motion.

9. The method as recited in claim 5, wherein step (c) includes iteratively minimizing the weighted least squares difference using a Levenberg-Marquardt algorithm.

10. The method as recited in claim 9, wherein the Levenberg Marquardt algorithm includes a diagonally-preconditioned conjugate gradient algorithm iteratively solving each Levenberg Marquardt step.

11. The method as recited in claim 1, wherein steps (a) and (b) are performed in a single scan of the subject.

12. The method as recited in claim 11, wherein steps (a) and (b) are performed sequentially.

13. The method as recited in claim 11, wherein steps (a) and (b) are repeatedly performed to acquire the first data and the second data, such that repetitions of step (a) are interleaved with repetitions of step (b).

14. The method as recited in claim 1, wherein step (d) includes Fourier transforming the signal that is jointly-estimated in step (c).
